(19) United States
(12) Patent Application Publication
(10) Pub. No.: US 2007/0258314 A1
(43) Pub. Date: Nov. 8, 2007

(54) DRIVING METHOD BASED ON A BINARY ARCHITECTURE

(75) Inventors: Gary Chiu, Longtan (TW); Jiun-Shiung Liau, Rowland Height, CA (US)

Correspondence Address: PAI PATENT & TRADEMARK LAW FIRM, 1001 FOURTH AVENUE, SUITE 3200, SEATTLE, WA, 98154, US

(73) Assignee: ZIEP SOFTWARE INC., Rowland Height, CA (US)

(21) Appl. No.: 11/672,222

(22) Filed: Feb. 7, 2007

(30) Foreign Application Priority Data
Feb. 9, 2006 (TW) 95104447
Dec. 15, 2006 (TW) 95147211

(51) Int. Cl. G11C 8/00

(52) U.S. Cl. 365/230.06

(57) ABSTRACT

A driving method for driving a peripheral device, based on a binary architecture, includes loading a description file by the middleware according to the device ID of the peripheral device; parsing the description file to generate driving instructions by the middleware; and driving the peripheral device by the driving instructions, in which the description file defines a driving information of the peripheral device.

### RELATED APPLICATIONS

The present application is based on, and claims priority from, Taiwan Application Serial Number 95104447, filed Feb. 9, 2006, the disclosure of which is hereby incorporated by reference herein in its entirety.

This application is also related to and claims priority from, Taiwan Application Serial Number 95147211, filed Dec. 15, 2006, the disclosure of which is hereby incorporated by reference herein in its entirety.

### BACKGROUND

1. Field of Invention

The present invention relates to a driving method based on a binary architecture. More particularly, the present invention relates to a driving method for driving a peripheral device.

2. Description of Related Art

Conventional software structures generally include application software, an operating system (OS, such as a linux kernel) and a peripheral device driver. The OS includes system calls and device drivers, in which the application software communicates with the peripheral device through the OS. The OS connects with the peripheral device through the device driver, while it also connects to the application software through system calls.

However, there are some problems in the conventional software structure, in which a device is driven by its own individual driver. The driver of the conventional software structure needs to be rebuilt and reinstalled if the peripheral device is changed. Unfortunately, the functions of the device driver cannot be on-line modified after being installed, such that another device driver needs to be installed for driving another peripheral device.

FIG. 1 illustrates the conventional software operation flow. The conventional software operation flow includes application software 120, the operating system 110 and the peripheral device 100, in which the operating system 110 includes the system call 112 and the device driver 114 specifically designed for the peripheral device 100. The peripheral device 100 usually contains a device configuration space 101. For the device driver 114, each field in device configuration space 101 has its own specific meaning. Take device A and device B for example. The device driver 114 parses the device configuration fields 105 and 107 of device A as the working frequency and the memory size. However, the device configuration field 105 of the device B may not also represent the working frequency. Because the device driver 114 cannot be modified on line after being installed, thus users must go through the trouble to re-install other device drivers again in order to drive device B. In other words, the conventional software operation flow is confined by the rule of one-device-one-driver relationship.

Taking the Wireless card as another example. The operating system triggers a Wireless card driver according to the Wireless card's device ID after being detected by the OS. Then, the operating system maps the input/output space (I/O space) and memory space of the Wireless card to the host system input/output space (host system I/O space) and host system memory respectively. The Wireless card driver provides some operation functions, such as open, close, packets_transmit, get_status and so on, with the OS to access the Wireless card. Then the Wireless card is initialized.

However, different Wireless cards contains different I/O space, different memory spaces and different register commands parameters, such as different I/O space sizes and different I/O space start addresses. Therefore, specific driver need to be established for individual wireless card, which complexes the installing process.

For the forgoing reasons, there is a need for a new driving method which is capable of driving various kinds of peripheral devices without reinstalling another device driver, and providing true plug and play for users.

### SUMMARY

According to one embodiment of the present invention, a Zero Installation Easy Porting (ZIEP) driving method for driving a peripheral device includes loading a description file by the middleware according to the device ID of the peripheral device; parsing the description file to generate driving instructions by the middleware; and driving the peripheral device by the driving instructions, in which the description file defines a driving information of the peripheral device.

The middleware automatically generates the required driving instructions and driving information, and does not need to re-install another device driver.

It is to be understood that both the foregoing general description and the following detailed description are by examples, and are intended to provide further explanation of the invention as claimed.

### BRIEF DESCRIPTION OF THE DRAWINGS

These and other features, aspects, and advantages of the present invention will become better understood with regard to the following description, appended claims, and accompanying drawings where:

FIG. 1 is conventional software operation flow;

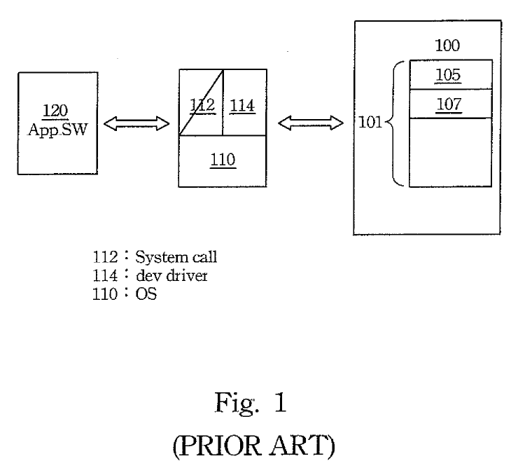

FIG. 2 is the Zero Installation Easy Porting (ZIEP) software architecture according to one embodiment of present invention;

FIG. 3 is the peripheral device and its description file according to one embodiment of present invention;

FIG. 4 is the flowchart of the driving method based on the binary architecture according to one embodiment of present invention; and

FIG. 5 is the description files of a PCI Wireless card according to another embodiment of present invention.

### DESCRIPTION OF THE PREFERRED EMBODIMENTS

Reference will now be made in detail to the present preferred embodiments of the invention, examples of which are illustrated in the accompanying drawings. Wherever possible, the same reference numbers are used in the drawings and the description to refer to the same or like parts.

According to one embodiment of the present invention, the operating system triggers the middleware which does not contain information about the peripheral devices. The primary function of the middleware is to parse the description file of the peripheral device to generate driving information, for example, the driving parameters and driving flows, and to bind the generated driving information to the operating system (OS). The information about the peripheral devices is kept in the corresponding description file.

Furthermore, the middleware combined with various description files is capable of driving various peripheral devices. It can also change/add the functions of the same peripheral device by simply modifying the description file, leaving middleware unchanged. Thus, the driving method is not confined by the relationship of one-device-one-driver.

The following describes the relationship and the driving flows among the operating system, the middleware and the description file. It further describes how the middleware generates the driving information by parsing the description file to drive a peripheral device.

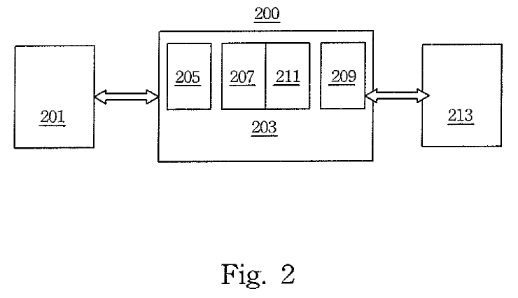

FIG. 2 is the Zero Installation Easy Porting (ZIEP) software architecture according to one embodiment of the present invention. The ZIEP software architecture 200 includes application software 201, an operating system 203, and a peripheral device 213, in which the application software 201 and the operating system 203 are disposed in a host controller (not shown), such as a personal computer, a personal digital assistant or a smart phone. The operating system 203 includes a set of standard system calls 205, middleware 207, driving instructions 211 generated by the middleware 207, and bus driver 209. The operating system 203 not only provides a standard system calls 205 for the application software 201, but also uses driving instructions 211 to access the peripheral device 213 through the bus driver 209.

The middleware 207 is triggered by the operating system 203. Once the operating system 203 detects that the peripheral device 213 is connected, the operating system 203 loads the device ID of the peripheral device 213. If the device ID of the peripheral device 213 shows that the peripheral device 213 supports ZIEP technology, the operating system 203 triggers the middleware 207 first, then the middleware 207 loads the description file of the peripheral device 213, in which the description file can be a text file. The description file can be stored in the peripheral device 213, the Internet, or a mass storage media, such as hard disc. After the middleware 207 gets the description file, the middleware parses the configuration, the driving parameters, and the driver execution flow of the peripheral device 213 according to the description file to generate suitable driving instructions to drive the peripheral device 213.

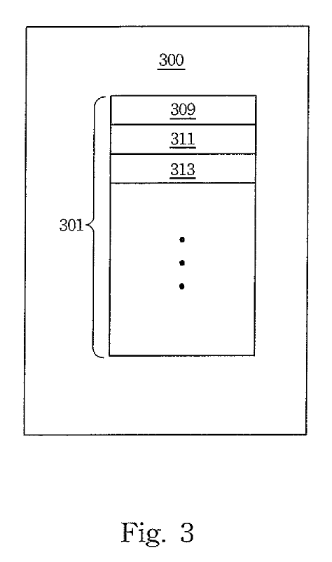

FIG. 3 is the peripheral device and its description file according to one embodiment of the present invention. The description file 301 includes the device configuration space 309, the driving parameters description block 311, and the driver execution flow description block 313. For example, if the peripheral device 300 is a CD/DVD ROM, the device configuration space 309 might define the access speed, the open, the close, and the media type of the CD/DVD ROM, while the driving parameters description block 311 and the driver execution flow description block 313 might define the needed driving parameters and the driving flows of the CD/DVD ROM respectively.

A middleware combined with various description files can drive different peripheral devices. It can also change/add other functions of the same device simply by modifying the description file, leaving middleware unchanged. Because the description file is not embedded in driver code, so it can be replaced or modified on line. As a result of changing the description file, the middleware generates new driving instructions based on the newly loaded description file to drive the new peripheral device.

For example, if the peripheral device 300 (such as CD/DVD ROM) is replaced with a display device, the middleware 207 generates new driving instructions to drive the display device automatically according to the newly loaded description file which describes the characteristic of the display device. Users do not need to install another driver for the display device. The description file can be modified by loading the relevant updates via the Internet, or can be re-written by the manufacturer or the user.

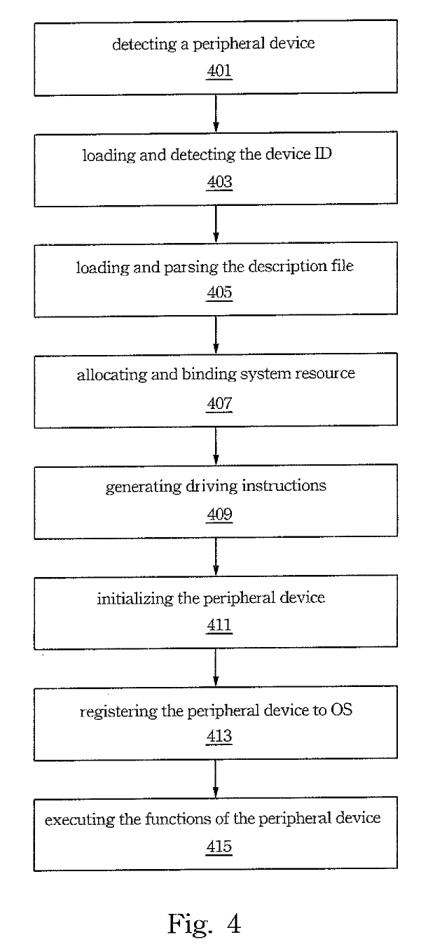

FIG. 4 is the flowchart of the driving method based on the binary architecture according to one embodiment of the present invention. These steps includes detecting a peripheral device in step 401, loading and detecting the device ID in step 403, loading and parsing the description file in step 405, allocating and binding system resources in step 407, generating driving instructions in step 409, initializing the peripheral device in step 411, registering the peripheral device to OS in step 413, and executing the functions of the peripheral device in step 415.

To drive the peripheral device, the first is detecting a peripheral device in step 401. In the step 401, the OS detects a peripheral device when the peripheral device connects to a host controller. Next, in step 403, the OS loads and detects the device ID to determine if the connected peripheral device supports the ZIEP technology according to the device ID. If it does, the middleware is triggered to execute the loading and parsing in step 405 to load and parse the corresponding description file according to the loaded device ID.

After the middleware loads and parses the description file in step 405, the middleware requests the allocating and binding in step 407 to allocate and bind system resources required by the peripheral device according to the parsing result. Then the middleware generates corresponding driving instructions to drive the peripheral device according to the description file in step 409, and stores the generated driving instructions and the configuration information into the allocated system resources.

After the generating step 409, the middleware performs the initializing in step 411. In step 411, the middleware uses the generated instructions to test the peripheral device, reset and initialize the peripheral device, as well as check if the initialization is successful. For example, if the peripheral device is a CD/DVD ROM, the middleware uses the generated driving instructions to test if the functions of open, the close, and the access of the CD/DVD ROM are correct.

Next, the middleware performs the registering in step 413 to register the peripheral device to the OS, and performs the executing in step 415 to execute the functions of the peripheral device. Hereafter, the application software can work with the peripheral device.

Taking PCI Wireless card as another embodiment of present invention. The driving method for driving the PCI Wireless card includes detecting a PCI wireless card; loading and detecting the device ID; loading and parsing the description file; allocating and binding system resources; generating driving instructions; initializing the PCI wireless card; registering the PCI wireless card to OS; and executing the functions of the PCI wireless card, which are further described in the following.

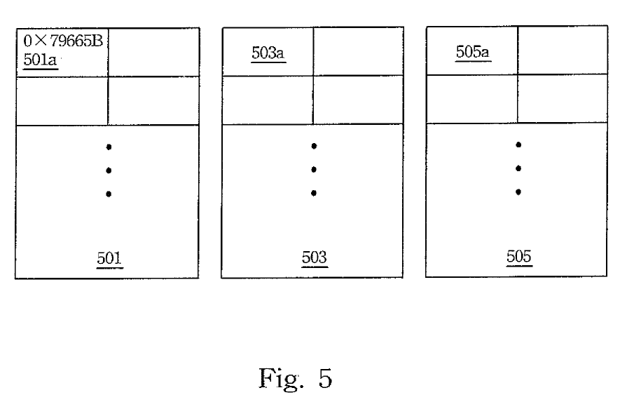

FIG. 5 shows the description files of a PCI Wireless card according to another embodiment of the present invention. The device ID fields 501a, 503a, and 505a are disposed in the description file 501, 503 and 505 respectively. If the OS detects that the device ID of the PCI Wireless card (0x79665B) supports ZIEP technology, the operating system triggers the middleware. Next, the middleware loads the description file which has the corresponding device ID in its device ID field. For example, if the device ID of the PCI wireless card is 0x79665, the middleware loads and parses the description file 501.

After the corresponding description file has been loaded, the middleware parses the description file of the PCI wireless card to produce the outputs (such as I/O space parameters and memory space parameters), and stored these outputs into the resource request list. For example, the parameter “ziep_e_open” defined in the description file is parsed, and parsed result is stored into the resource request list.

Next, the middleware allocates and binds system resources. The middleware maps the I/O spaces and the memory spaces of the PCI wireless card to the host system I/O and the host system memory respectively according to the resource request list. While the PCI Wireless cards is changed to another peripheral device, corresponding description file is loaded and parsed again to produces another set of resource request list.

With the automatic generated resource request lists, middleware can flexibly map different I/O spaces and different memory spaces to the host system I/O and the host system memory if the device is changed. Therefore, one middleware with different description files can drive various types of peripheral devices.

Then the middleware generates the driving instructions by combining the driver API's and the driving flows. The middleware provides the OS kernel with driver API's defined in the description file, such as ziep_e_open, ziep_e_close, ziep_get_stats, and ziep_start_xmit, and associates these driver API's with the system calls.

After generating the driving instructions, the middleware is able to access the PCI Wireless card by referencing the parameters in the resource request list with the system resources. Therefore, the middleware can initialize a device according to the initialization description in the description file.

Once the wireless card has been initialized, the host controller can communicate with the PCI Wireless card. It uses the mapped host system I/O to control the PCI Wireless card, in which the host system I/O in the host controller is mirrored mapping from the I/O spaces in the PCI wireless card. The I/O_registers in the description file states the offset address, the access flow, and the access right (W: write; R: read; A: read and write) of each register.

Then, the middleware writes the device information into the device table of operating system, which registers the PCI wireless card. Hereafter, the OS is aware of the existence of the PCI Wireless card, and the functions of the PCI Wireless card are ready for executing.

The ZIEP driving method can drive peripheral devices such as a wireless card, a printer, a monitor, a CD/DVD ROM, an audio card, a 3D display card, a bluetooth wireless card, a wimax wireless card, a USB interface device, a PCI/CardBus/PCMCIA interface device, a SD interface device, or a IEEE 1394 interface device.

In summary, the ZIEP driving method can generate driving instructions to drive various kinds of peripheral devices by simply modifying the description file. Furthermore, the same peripheral device can function or behave differently by modifying the description file.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

What is claimed is:

1. A driving method for driving a peripheral device, based on a binary architecture, the driving method comprising:
loading a description file by a middleware according to a device ID of the peripheral device;
parsing the description file to generate driving instructions by the middleware; and
driving the peripheral device by the driving instructions, wherein the description file defines a driving information of the peripheral device.

2. The method of claim 1, wherein the driving information comprises driving parameters and driving flows of the peripheral device.

3. The method of claim 1, further comprising using the driving instructions to initialize the peripheral device by the middleware, whereby the correctness of the functions of the peripheral device is confirmed.

4. The method of claim 1, wherein the middleware is triggered by an operating system of a host controller according to the device ID.

5. The method of claim 4, wherein the host controller is a personal computer, a personal digital assistant or a smart phone.

6. The method of claim 4, wherein the description file is stored in the host controller.

7. The method of claim 4, further comprising allocating and binding system resources in the host controller based on parsing the description file by the middleware.

8. The method of claim 7, wherein the middleware maps a memory spaces of the peripheral device to a host system memory in the system resources.

9. The method of claim 7, wherein the middleware maps an input/output spaces of the peripheral device to a host system input/output space in the system resources.

10. The method of claim 7, further comprising storing the driving instructions and the driving information into the system resources by the middleware.

11. The method of claim 7, wherein the system resources are controlled by the middleware.

12. The method of claim 1, further comprising providing and associating a driver API's with system calls by the middleware, wherein the driver API's is defined in the description file.

13. The method of claim 1, wherein the description file is a text file.

14. The method of claim 1, wherein the description file is stored in the peripheral device or a mass storage device.

15. The method of claim 1, wherein the description file is stored on the Internet.

16. The method of claim 1, wherein the peripheral device is a wireless card, a printer, a monitor, a CD/DVD ROM, an audio card, a 3D display card, a bluetooth wireless card, or a wimax wireless card.

17. The method of claim 1, wherein the peripheral device is a USB interface device, a PCI/CardBus/PCMCIA interface device, a SD interface device, or a IEEE 1394 interface device.
